(19) United States
(12) Patent Application Publication
(10) Pub. No.: US 2013/0044421 A1
(43) Pub. Date: Feb. 21, 2013

(54) ELECTRONIC APPARATUS, ELECTRONIC APPARATUS SYSTEM, AND PCI CARD MOUNTING STRUCTURE

(71) Applicant: Kengo UEDA, Kawasaki (JP)

(72) Inventor: Kengo UEDA, Kawasaki (JP)

(73) Assignee: FUJITSU LIMITED, Kawasaki-shi (JP)

(21) Appl. No.: 13/534,102

(22) Filed: Jun. 27, 2012

(30) Foreign Application Priority Data
Aug. 15, 2011 (JP) 2011-177656

(51) Int. Cl. H05K 5/00; G06F 1/16; H05K 7/20

(52) U.S. Cl. 361/679.02; 361/752; 361/694

(57) ABSTRACT

An electronic apparatus includes: a housing to include a back surface having an uneven difference which is formed by a part of the back surface going backward; a card storage unit to include an first opening on the back surface of the housing and store a card substrate; and a relay substrate, provided inside the card storage unit, to include a connecter to be coupled to a connecter of the card substrate; and a second opening provided on a side surface of the uneven difference of the housing so that a bracket of the card substrate is exposed on an outside of the electronic apparatus while storing the card substrate in the card storage unit.

### CROSS-REFERENCE TO RELATED APPLICATIONS

This application is based upon and claims the benefit of priority from the prior Japanese Patent Application No. 2011-177656 filed on Aug. 15, 2011, the entire contents of which are incorporated herein by reference.

### FIELD

The embodiments discussed herein are related to an electronic apparatus.

### BACKGROUND

A server to be coupled via the Internet or LAN is coupled to many information processing devices such as a network apparatus or a file device. To provide a plurality of servers in one position, a rack mount method for mounting a plurality of servers by being stacked on a unit chassis called a rack may be employed. According to the rack mount method, a plurality of information processing devices including a server is effectively provided in an office or the like, so that increase of apparatuses or security management may be easily performed.

An I/O card (hereinafter referred to as PCI card (including PCI express card)) that is compliant with Peripheral Component Interconnection (PCI) standard may be used as an I/O interface in the server. PCI standard includes, for example, PCI-X standard, PCI Express standard, or the like.

The related technique is disclosed in Japanese Laid-open Patent Publication No. 11-3137 or Japanese Laid-open Patent Publication No. 2003-173216.

### SUMMARY

According to one aspect of the embodiments, an electronic apparatus includes a housing to include a back surface having an uneven difference which is formed by a part of the back surface going backward; a card storage unit to include an first opening on the back surface of the housing and store a card substrate; a relay substrate, provided inside the card storage unit, to include a connecter to be coupled to a connecter of the card substrate; and a second opening provided on a side surface of the uneven difference of the housing so that a bracket of the card substrate is exposed on an outside of the electronic apparatus while storing the card substrate in the card storage unit.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF THE DRAWINGS

FIG. 1 illustrates an exemplary electronic apparatus;

FIG. 2 illustrates an exemplary housing;

FIG. 3 illustrates an exemplary server;

FIG. 4 illustrates an exemplary server;

FIG. 5 illustrates an exemplary server;

FIG. 6 illustrates an exemplary server;

FIG. 7 illustrates an exemplary server;

FIG. 8 illustrates an exemplary server;

FIG. 9 illustrates an exemplary server;

FIG. 10 illustrates an exemplary server; and

FIG. 11 illustrates an exemplary server.

### DETAILED DESCRIPTION OF EMBODIMENTS

A structure for attaching a PCI card to a server depends on manufactures. The PCI card is attached to a main substrate of an electronic apparatus so as to be inserted into and removed from a main substrate. Since the PCI card is coupled to an external apparatus, a connecter used to couple a bracket of the PCI card to the external apparatus is provided. While the PCI card is embedded in the electronic apparatus, an external coupling cable is coupled to the connecter of the bracket that is exposed on the outside thereof.

The PCI card may be attached to an internal main substrate from the upper surface of the electronic apparatus (the connecter of the PCI card may be coupled to the connecter of the main substrate.). An operation space in which the PCI card is attached is provided on the upper part of a housing of the electronic apparatus. According to the rack mount method for stacking electronic apparatuses, no operation space may be provided on the upper part of the electronic apparatus.

When the PCI card embedded in a cassette is embedded in the housing of the electronic apparatus together with the cassette, the number of the PCI cards to be attached to the electronic apparatus may be decreased to provide the space for the cassette. Because of the cost of the cassette, the cost of the electronic apparatus may increase.

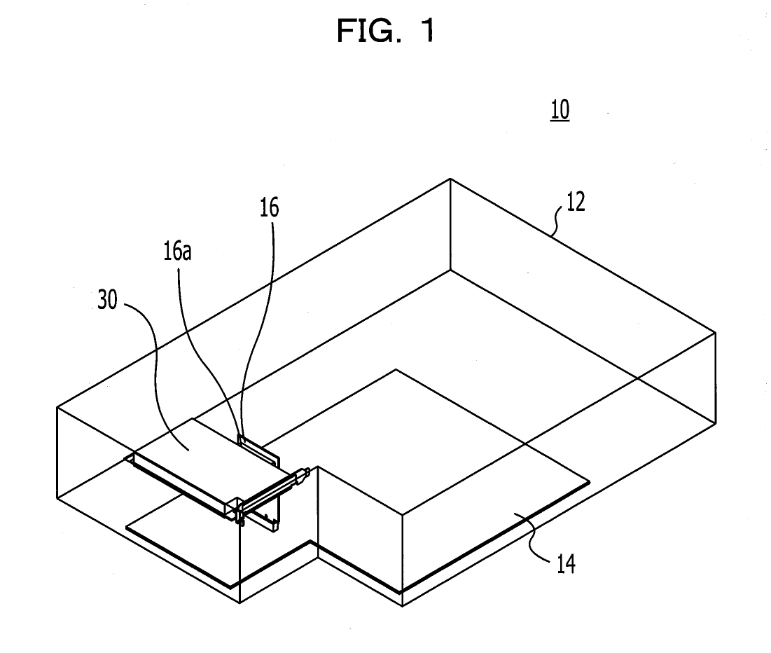

FIG. 1 illustrates an exemplary electronic apparatus. The electronic apparatus illustrated in FIG. 1 may be a server on which a PCI card is mounted. FIG. 1 illustrates a perspective diagram of the server. A main substrate 14 on which an electronic circuit with a server function is formed is embedded in a housing 12 of a server 10. Inside the housing 12, other function parts such as a cooling fan and the like as well as the main substrate 14 are provided. However, the function parts may not be illustrated in the diagram for convenience sake.

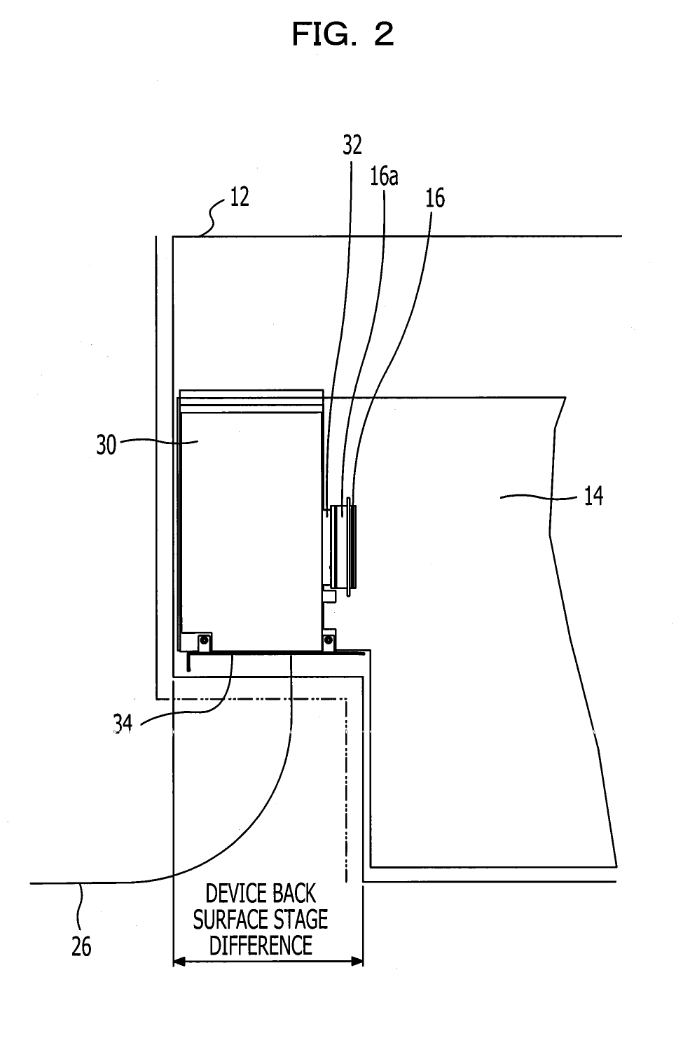

A corner part of the back surface of the housing 12 is notched so that an uneven difference is provided on the back surface of the housing 21. FIG. 2 illustrates an exemplary housing. FIG. 2 may be a plane diagram of the uneven difference of the housing 12 viewed from above.

The main substrate 14 is horizontally provided at a bottom of the housing 12. When the main substrate 14 is horizontally provided, a connecter 32 of a PCI card 30 is coupled to a connecter 16a of a relay substrate 16. The relay substrate 16 perpendicularly rises from the main substrate 14. The PCI card 30 is inserted in the housing 12 from the back surface of the server 10, and the connecter 32 of the PCI card 30 is coupled to the connecter 16a.

A plurality of PCI cards 30 is stacked. FIG. 1 illustrates the PCI card 30 that is on the top.

When the PCI card 30 is stored in the housing 12 and the connecter 32 is coupled to the connecter 16a of the relay subtract 16, a bracket 34 of the PCI card 30 is exposed from the side surface of the uneven difference of the housing 12. Therefore, an external coupling cable 40 may be coupled to a connecter (not illustrated) provided in the bracket 34. In FIG. 2, one external coupling cable 26 is illustrated as a solid line for convenience sake. The external coupling cable 26 may be thick and more than one.

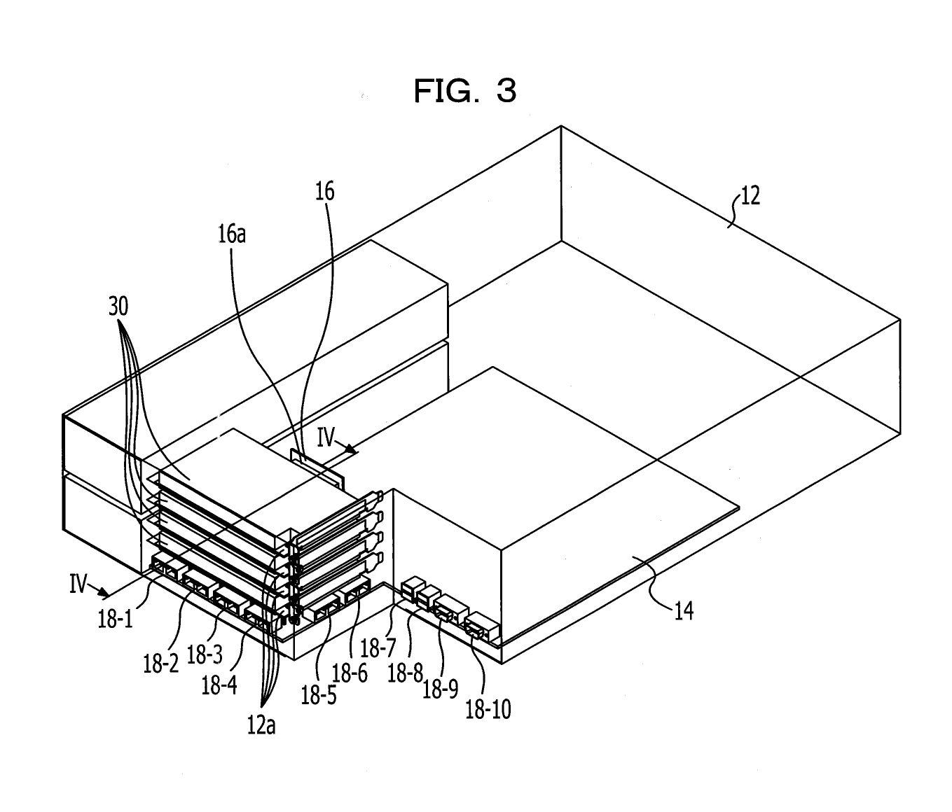

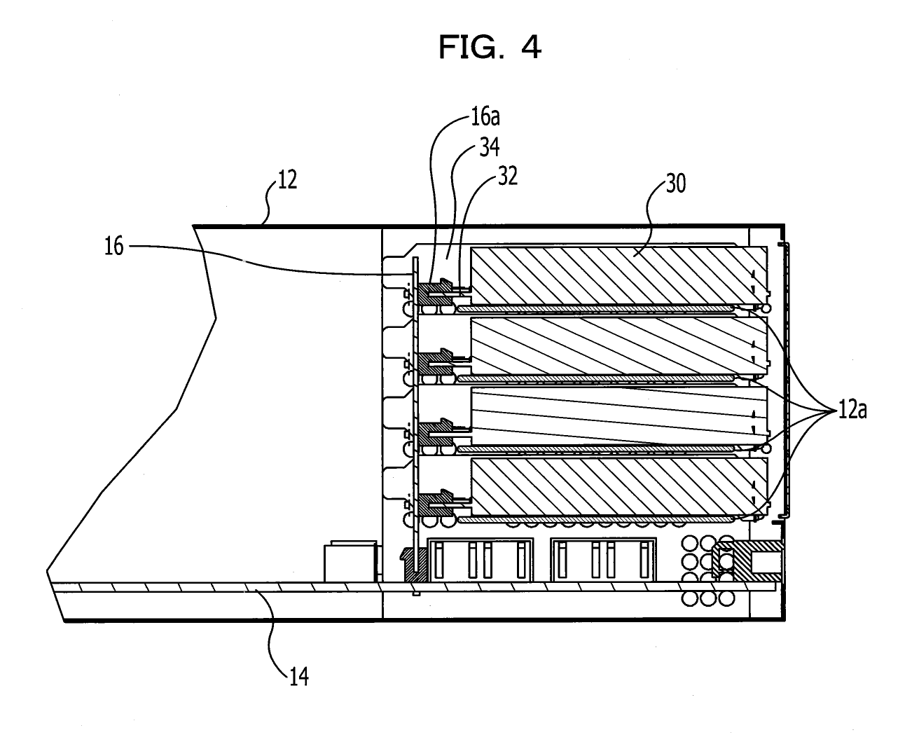

FIG. 3 and FIG. 4 illustrate an exemplary server. FIG. 3 is a perspective view illustrating the inside of the server 10 in which a plurality of PCI cards 30 is embedded. Each of four PCI cards 30 is horizontally inserted in a slot provided on the back surface of the housing 12, and the four PCI cards 30 are vertically stacked in the vertical direction to be stored in the housing 12. FIG. 4 may be a cross-section diagram along an IV-IV line illustrated in FIG. 3. Inside the housing 12, four PCI slots that are divided by an inter-PCI slot division plate 12a in the vertical direction are formed. One PCI card 30 is inserted in one PCI slot.

The PCI card 30 is inserted in the PCI slot in such a way that the bracket 34 matches an opening 12b that is formed on a side surface 12A in the uneven difference of the housing 12. When the PCI card 30 is inserted in the PCI slot, the position of the connecter 32 of the PCI card 30 is opposite to the connecter 16a of the relay substrate 16. Accordingly, when the PCI card is completely inserted in the PCI slot, the connecter 32 of the PCI card 30 is automatically coupled to the connecter 16a of the relay substrate 16. When the horizontal PCI card 30 is inserted in a desired PCI slot, the mounting of the PCI card 30 is completed.

Various connecters 18-1 to 18-10 are attached to an end part of the main substrate 14. A space may be provided between the PCI card 30 on the lowest stage and the main substrate 14. Therefore, the connecters 18-1 to 18-4 may be provided also in a part along the back surface of the device as an edge part of the main substrate 14 in the part where the PCI card 30 is provided. The connecters 18-5 and 18-6 may be provided also in a part along the side surface 12A of the uneven difference of the housing 12. The connecters 18-7 to 18-10 may be provided also in the part along a back surface 12B of the uneven difference of the housing 12. The connecter is provided in all the parts as the edge part of the main substrate 14 along the dashed line illustrated in FIG. 2. Even if the PCI card 30 is mounted from the back surface of the device, the connecter may be provided along the edge of the main substrate 14. Therefore, regarding the mounting of the PCI card 30, the number of the connecters to be provided on the main substrate 14 may not be limited.

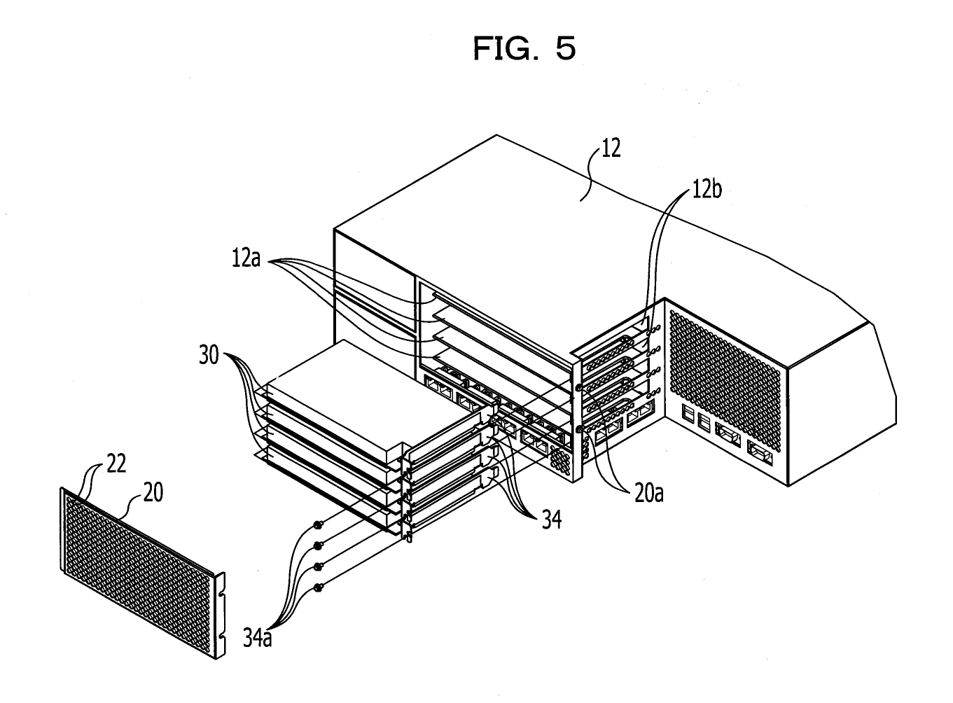

FIG. 5 illustrates an exemplary server. FIG. 5 may be a perspective view of the back surface of the server 10 before the PCI card is inserted in the PCI slot. After the PCI card 30 is inserted in the PCI slot that is divided by the inter-PCI slot division plate 12a, the back edge part of the bracket 34 is fixed to the housing 12 with screws 34a. After the PCI card 30 is inserted in the PCI slot, a PCI slot cover 20 is attached to the back surface of the housing 12 to cover the PCI slot. The PCI slot cover 20 is fixed to the housing 12 with screws 20a. Exhaust holes 22 are provided on the entire surface of the PCI slot cover 20, so that the air inside the housing 12 may be exhaled to the outside of the housing 12 through the exhaust holes 22.

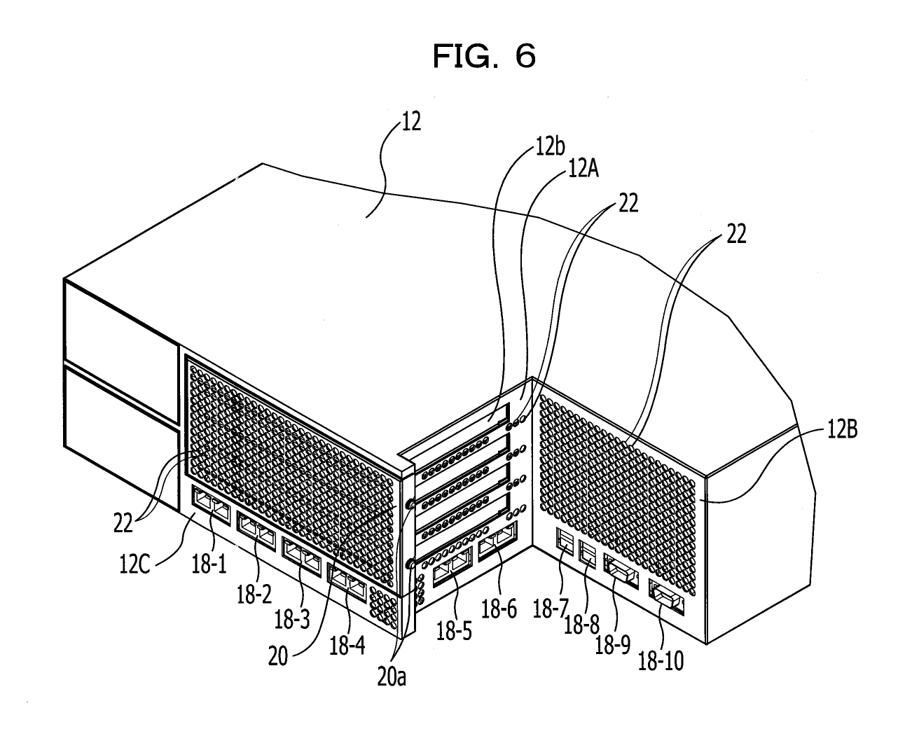

FIG. 6 illustrates an exemplary server. FIG. 6 may be a perspective diagram illustrating the back surface of the server 10 to which the PCI slot cover 20 is attached. On the side surface 12A of the uneven difference of the housing 12, the exhaust holes 22 are provided in a part other than the opening 12b so that the air (warm air) inside the housing 12 is exhaled to the outside of the housing 12 through the exhaust holes 22. The exhaust holes 22 are provided also on the entire surface of the back surface 12B of the uneven difference of the housing 12, so that the air (warm air) inside the housing 12 may be exhaled to the outside of the housing 12 through the exhaust holes 22. Even if the PCI card 30 is attached from the back surface, the exhaust holes 22 are provided in a large part of the back surface of the housing 12. Therefore, the warm air is effectively exhaled from inside of the housing 12 so that cooling efficiency may be maintained.

The connecters 18-1 to 18-10 illustrated in FIG. 3 are exposed from a back surface 12C of the housing 12, the side surface 12A of the uneven difference of the housing 12, and the back surface 12B of the uneven difference of the housing 12, respectively. Thus, the connecter of the coupling cable may be coupled from outside of the housing 12.

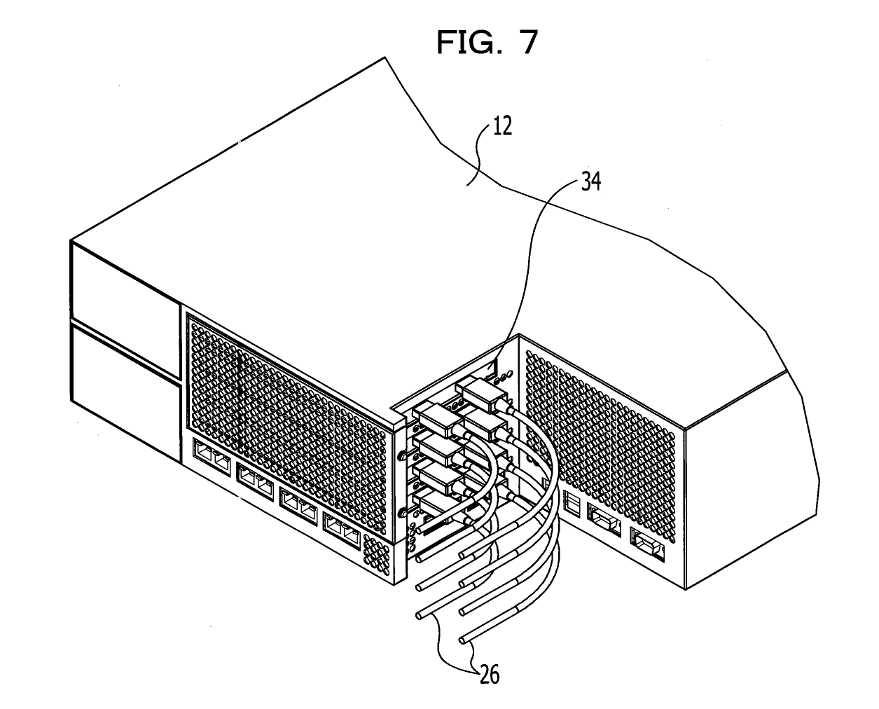

FIG. 7 illustrates an exemplary server. FIG. 7 may be a perspective diagram illustrating a state where an external coupling cable is attached to the PCI card 30. Inside the opening 12b of the side surface 12A of the uneven difference of the housing 12, the bracket 34 of the mounted PCI card 30 may be exposed. A connecter used to couple the external coupling cable is provided in the bracket 34 of the PCI card 30 even though the connecter is not illustrated in FIGS. 3 to 6. In FIG. 7, the connecter of the external coupling cable 26 may be coupled to each of the two connecters provided in the bracket 34 of one PCI card 30.

After the PCI card 30 is inserted in the PCI slot, the connecter of the external coupling cable 26 may be coupled to the connecter of the bracket 34 from the side surface 12A of the uneven difference. Therefore, the space of the uneven difference may be an operation space for coupling the external coupling cable 26 or a space in which the external coupling cable 26 coupled to the PCI card 30 is extended.

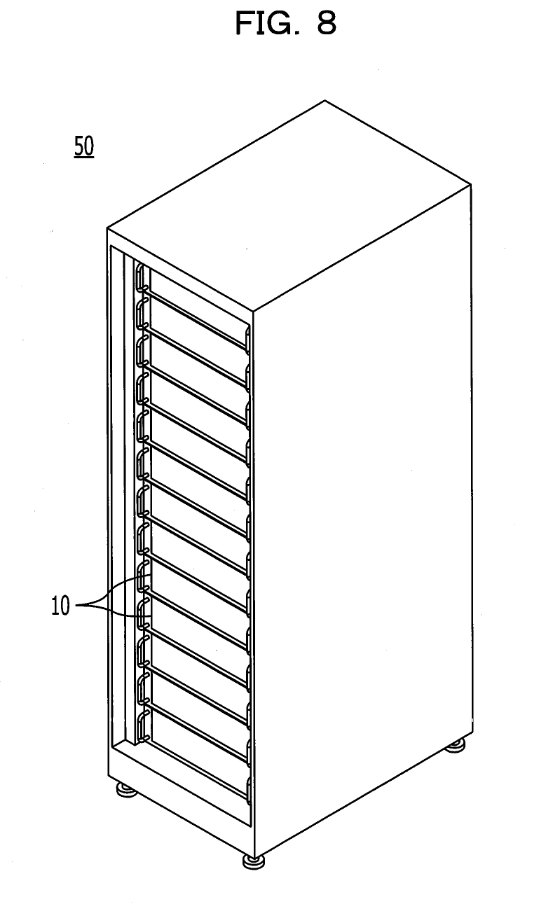

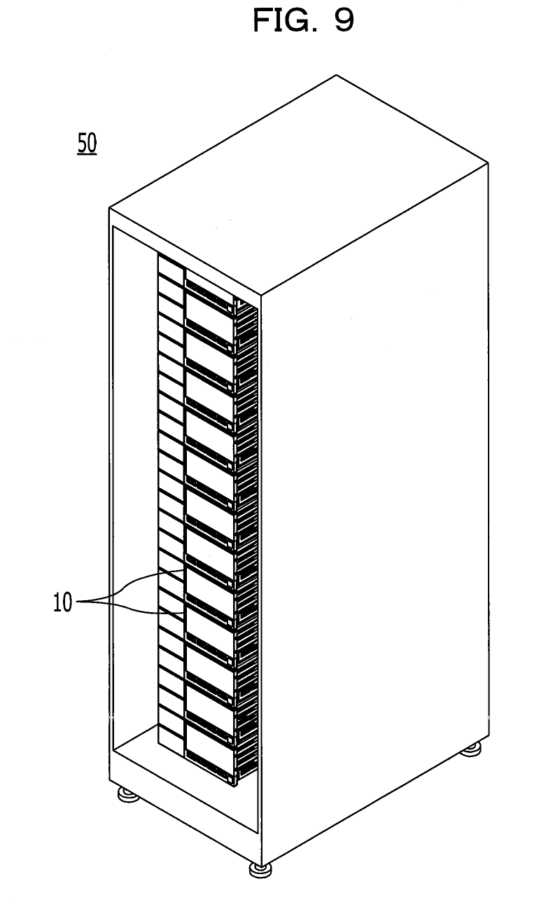

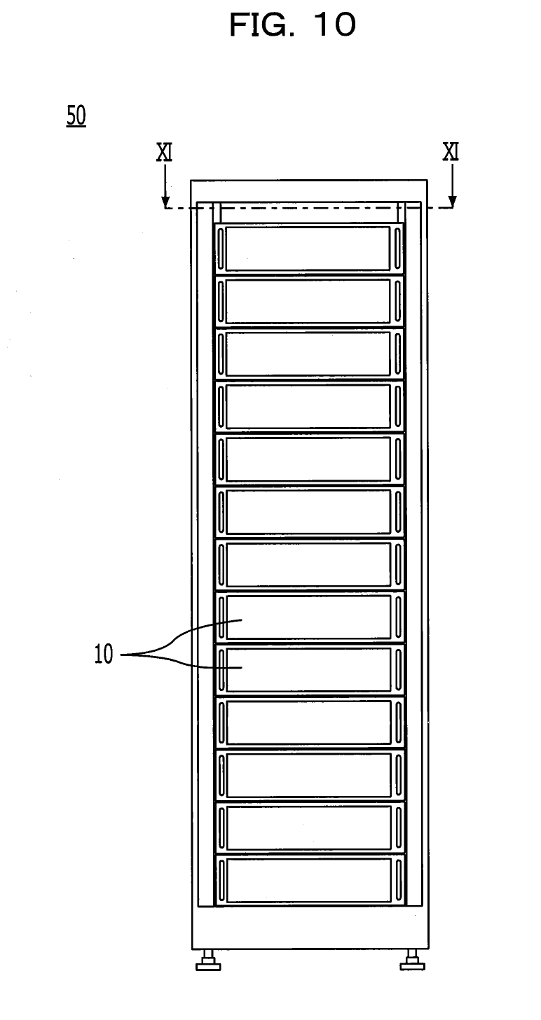

The server 10 on which the PCI card 30 is mounted may be loaded on the rack. FIGS. 8, 9, 10, and 11 illustrate an exemplary server. FIG. 8 may be a perspective diagram of the rack 50 on which the server 10 is mounted viewed from the front side thereof. FIG. 9 may be a perspective diagram of the rack 50 viewed from the back side thereof. FIG. 10 may be a front view of the rack 50. The rack 50 may store stacked thirteen servers 10. If the servers 10 are stored in the rack 50, the upper surface and the lower surface of the server 10 get close to or contact another server 10. Accordingly, the exhaust hole may not be provided on the upper surface or the lower surface of the server 10. Since the structure of the rack does not consider the exhaust from the side surface of the server 10, the exhaust hole is not provided on the side surface of the server 10.

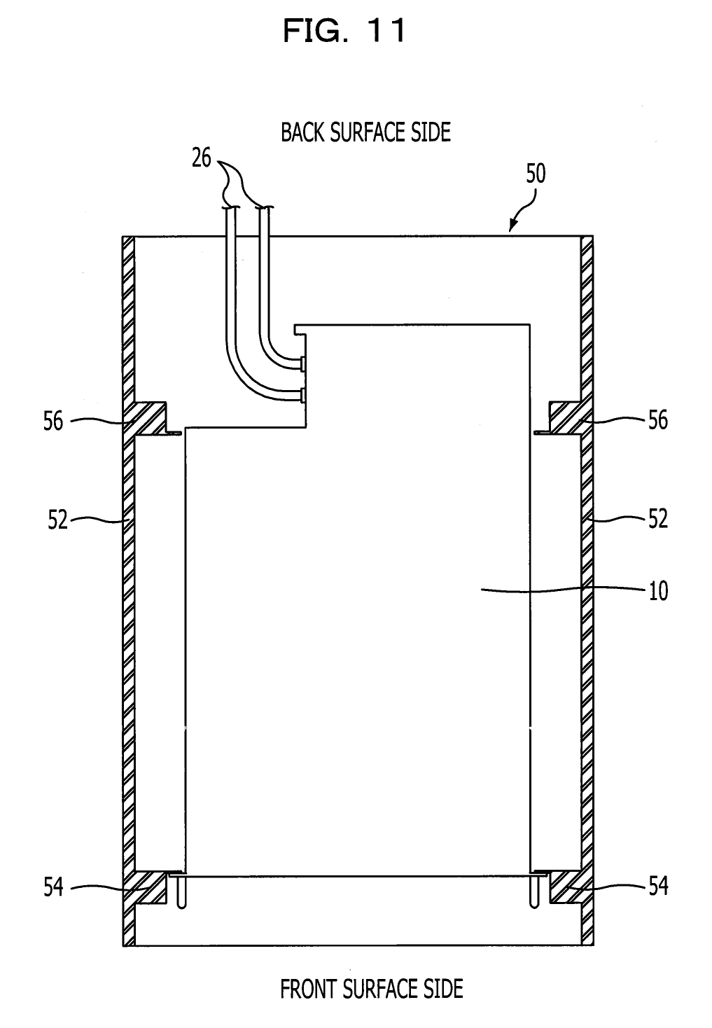

FIG. 11 may be a cross-section diagram along an XI-XI line illustrated in FIG. 10. The rack 50 includes a pair of front columns 54 and a pair of posterior columns 56, and the front columns 54 and the posterior columns 56 support side walls 52 located on the right side and the left side. When the server 10 is stored in the rack 50, the side surfaces of the server 10 get close to the front columns 54 and the posterior columns 56. Therefore, the exhaust may not be performed from the back surface of the rack 50. Many exhaust holes 22 are provided on the back side of the server 10, and the server 10 may be efficiently cooled.

The PCI card 30 to be exchanged is removed from the PCI slot of the server 10 to exchange the PCI card 30 mounted on the server 30. After the operation of the removed PCI card 30 is stopped, the external coupling cable 26 is removed from the PCI card 30. The above-described operation may be easily performed in the operation space provided in the uneven difference on the back side of the server 10.

The PCI slot cover 20 is removed from the back surface of the server 10, and the PCI card 30 to be exchanged is removed from the PCI card slot. The direction in which the connecter 32 of the PCI card 30 is removed from the connecter 16a of the relay substrate 16 may be similar to the direction in which the PCI card 30 is removed from the PCI card slot. Therefore, when the PCI card 30 is removed, the PCI card 30 may be removed from the relay substrate 16.

After the operation of the PCI card 30 to be exchanged is stopped, the PCI card 30 may be easily removed from the server 10. Therefore, the server that is subjected to maintenance and inspection is removed from the rack, and the operation for opening the housing of the server 10 and removing the internal PCI card is not performed. The PCI card 30 is individually removed from the relay substrate 16. Therefore, during the operation of another PCI card 30 that is coupled to the relay substrate 16 coupled to the PCI card 30 to be exchanged, a desired PCI card 30 may be removed from the server 10.

Since the PCI card 30 is mounted without using the cassette that stores the PCI card 30, the operation for removing the PCI card from the cassette after removing the coupling of the cassette and the PCI card may not be performed.

The PCI card 30 is removed, and another PCI card 30 is attached to the server 10. For example, another PCI card 30 is inserted in the PCI card slot. Since the PCI card is inserted in the PCI card slot, the connecter 32 of the PCI card 30 is coupled to the connecter of the relay substrate 16. The attachment of the PCI card is completed.

When another PCI card 30 is completely inserted in the PCI card slot, the PCI slot cover 20 is attached to the back surface of the server 10. The removed external coupling cable 26 is newly coupled to the connecter of the bracket 34 of the PCI card 30. The operation for exchanging the PCI card 30 is completed, and the operation of the exchanged PCI card 30 is confirmed.

Simply the desired PCI card 30 may be exchanged while the operation of another PCI card 30 is maintained. The housing of the server 10 may not be opened and the relay substrate may not be removed. Complicated operation for removing or coupling the external coupling cable from or to a plurality of PCI cards may not be performed. Since the number of the operation processes is small, operation mistakes of the maintenance and inspection operation may be reduced. While the server 10 is stored in the rack 50, the maintenance and inspection operation is performed simply by the operation from the back surface. When the heavy server 10 is not removed from the rack 50, a single worker may perform the maintenance and inspection operation. Since the cassette is not used, the operation for removing the PCI card from the cassette, storing another PCI card in the cassette, or attaching the cassette to the server may not be performed.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention(s) has (have) been described in detail, it should be understood that the various changes, substitutions, and alterations could be made hereto without departing from the spirit and scope of the invention.

What is claimed is:

1. An electronic apparatus comprising:
a housing to include a back surface having an uneven difference which is formed by a part of the back surface going backward;
a card storage unit to include an first opening on the back surface of the housing and store a card substrate;
a relay substrate, provided inside the card storage unit, to include a connecter to be coupled to a connecter of the card substrate; and
a second opening provided on a side surface of the uneven difference of the housing so that a bracket of the card substrate is exposed on an outside of the electronic apparatus while storing the card substrate in the card storage unit.

2. The electronic apparatus according to claim 1, wherein the card storage unit includes a plurality of PCI card slots which are stacked.

3. The electronic apparatus according to claim 1, wherein the relay substrate is provided vertically to a circuit substrate in the housing.

4. The electronic apparatus according to claim 1 comprising, an external coupling connecter provided on a lower side of the card storage unit on a circuit substrate inside the housing.

5. The electronic apparatus according to claim 4, wherein the external coupling connecter is exposed on the outside of the housing.

6. The electronic apparatus according to claim 1 comprising, a cover which closes the first opening of the PCI storage unit,
wherein the cover includes an exhaust hole.

7. The electronic apparatus according to claim 1 comprising, an exhaust hole provided on the side surface of the uneven difference of the housing.

8. An electronic apparatus system comprising:
a plurality of electronic apparatuses stacked in a stack form,
wherein each of the plurality of electronic apparatuses includes:
a housing with a back surface on which a part of the back surface moves backward and an uneven difference is formed;
a housing to include a back surface having an uneven difference which is formed by a part of the back surface going backward;
a card storage unit to include an first opening on the back surface of the housing and store a card substrate; and
a relay substrate, provided inside the card storage unit, to include a connecter to be coupled to a connecter of the card substrate; and
a second opening provided on a side surface of the uneven difference of the housing so that a bracket of the card substrate is exposed on an outside of the electronic apparatus while storing the card substrate in the card storage unit.

9. The electronic apparatus system according to claim 8, wherein the card storage unit includes a plurality of PCI card slots which are tacked.

10. The electronic apparatus system according to claim 8, wherein the electronic apparatus is a server.

11. A PCI card mounting structure, comprising:
a housing to include a back surface having an uneven difference which is formed by a part of the back surface going backward;
a card storage unit to include an first opening on the back surface of the housing and store a card substrate;
a connecter, provided in an opposite side to the first opening, to be coupled to a connecter of the PCI card when the PCI card is inserted in the PCI storage unit; and
a second opening provided on a side surface of the uneven difference of the housing so that a bracket of the card substrate is exposed on an outside of the electronic apparatus while storing the card substrate in the card storage unit.

12. The PCI card mounting structure according to claim 11, wherein the card storage unit includes a plurality of PCI card slots which are stacked.
